(19) United States
(12) Patent Application Publication
(10) Pub. No.: US 2023/0246253 A1
(43) Pub. Date: Aug. 3, 2023

(54) Electrical Device and Method for Operating an Electrical Device

(71) Applicant: Robert Bosch GmbH, Stuttgart (DE)

(72) Inventors: Mickael Segret, Stuttgart (DE); Christoph Klee, Stuttgart (DE); Marc-Alexandre Seibert, Stuttgart (DE)

(21) Appl. No.: 18/003,397

(22) PCT Filed: Jun. 18, 2021
(86) PCT No.: PCT/EP2021/066592

§ 371 Date: Dec. 27, 2022

(30) Foreign Application Priority Data
Jul. 3, 2020 (DE) 10 2020 208 356.8

(51) Int. Cl. H01M 10/44; H01M 10/48; H02J 7/00

(52) U.S. Cl. CPC H01M 10/44; H01M 10/488; H02J 7/007

(57) ABSTRACT

An electrical device includes a housing with a first external contact and a second external contact for supplying the electrical device with power. The electrical device has a first conductor, a second conductor, and an evaluation unit in the housing. The first conductor is electrically connected to a first contact for a first potential. The second conductor is electrically connected to a second contact for a second potential that is different from the first potential. The first conductor and the second conductor are electrically connected to the evaluation unit. The first conductor and the second conductor are configured such that an electrical connection between the first conductor and the second conductor, due to dirt or moisture in the housing, is detected by the evaluation unit.

### PRIOR ART

The invention proceeds from an electrical device and a method for operating an electrical device.

An electrical device is protected against dirt or moisture by constructive measures.

In DE 10 2016 207 566 A1, a battery pack is described, which can discharge itself under certain conditions.

It is difficult to maintain such measures against dirt or moisture over a lifetime of the product. For example, mechanical influences may damage protection that constructive measures offer. Furthermore, in the event of a failure of an electrolytic capacitor or battery cell of the battery pack containing electrolyte, for example, dirt or moisture may also occur inside the electrical device.

### DISCLOSURE OF THE INVENTION

By an electrical device and a method for operating the electrical device according to the independent claims, an operational safety of the electrical device with respect to dirt or moisture is improved.

The electrical device comprises a housing with a first external contact and a second external contact for supplying the electrical device with power, wherein the electrical device comprises a first conductor, a second conductor and an evaluation unit in the housing, wherein the first conductor is electrically connected to a first contact for a first potential, wherein the second conductor is electrically connected to a second contact for a second potential that is different from the first potential, wherein the first conductor and the second conductor are electrically connected to the evaluation unit, wherein the first conductor and the second conductor are arranged in such a way that an electrical connection between the first conductor and the second conductor due to dirt or moisture in the housing can be detected by the evaluation unit. In this respect, conductive dirt or moisture can be detected irrespective of whether damage has occurred or not.

Preferably, the second conductor is electrically connected via a resistor to an input of the evaluation unit for detecting dirt or moisture. This resistor represents a protective resistor for the evaluation unit.

Preferably, the second conductor is electrically connected via a resistor to the second contact and an input of the evaluation unit for a supply voltage. This resistor may be a pull-up resistor to which, during operation of the electrical device, the supply voltage of the evaluation unit is applied. In this case, the supply voltage represents the second potential. Dirt or moisture can thereby be detected in an inexpensive manner.

Preferably, the first conductor is electrically connected to an input of the evaluation unit for a reference potential. In this case, the reference potential represents the first potential. A potential difference for a detection of dirt or moisture can thereby be represented in an inexpensive manner.

Preferably, the first conductor and the second conductor are arranged electrically insulated from one another and, in one region, at least in sections adjacent to one another and uninsulated from one another. This allows dirt or moisture to be detected in predetermined sections.

Preferably, the evaluation unit is configured to identify a failure if an electrical connection between the first conductor and the second conductor due to dirt or moisture has been detected, wherein the evaluation unit is configured to deactivate the electrical device in the event of a failure. This additionally increases operational safety.

Preferably, the electrical device comprises a battery cell and a discharge device, wherein the evaluation unit is configured to discharge the battery cell with the discharge device in the event of a failure. This additionally increases the operational safety of an electrical device powered by a battery cell.

Preferably, the electrical device comprises a charging device for a battery cell, wherein the evaluation unit is configured to deactivate the charging device in the event of a failure, or wherein the evaluation unit is configured to prevent charging of a battery cell by a charging device in the event of a failure. This additionally increases the operational safety of a charging device.

Preferably, in the electrical device, different pairs of the first conductor and second conductor are arranged electrically insulated from one another, which conductors are electrically connected to different inputs of the evaluation unit, wherein the evaluation unit is configured to determine a number of pairs for which the electrical connection is detected, wherein the evaluation unit is configured to determine a failure of the electrical device depending on the number. This allows identification of a degree of impairment of the operational safety of the electrical device due to dirt or moisture.

Preferably, in the electrical device, a first conductor and a plurality of second conductors are arranged adjacent to one another and electrically insulated from one another, wherein the evaluation unit is configured to determine a number of second conductors for which the electrical connection of the first conductor to the second conductor is detected, wherein the evaluation unit is configured to determine a failure of the electrical device depending on the number. This allows identification of a size or type of contamination or an amount of moisture present in the electrical device.

The method for operating the electrical device in which at least one first conductor, at least one second conductor and an evaluation unit are arranged, wherein the at least one first conductor is electrically connected to a contact for a first potential, wherein the at least one second conductor is connected to a contact for a second potential that is different from the first potential, wherein the at least one first conductor and the second conductor are electrically connected to the evaluation unit, wherein the at least one first conductor and the at least one second conductor are arranged in such a way that an electrical connection between at least one first conductor and at least one second conductor due to dirt or moisture can be detected by the evaluation unit, provides that when an electrical connection of at least one first conductor and at least one second conductor due to dirt or moisture is detected by evaluation unit, a failure is identified, wherein, in the event of a failure, the electrical device is deactivated, a battery cell is discharged with a discharge device or a charging device is deactivated or charging with a charging device is prevented. This improves the operational safety of the electrical device over its service life.

Further advantageous embodiments result from the following description and the drawing. Shown are:

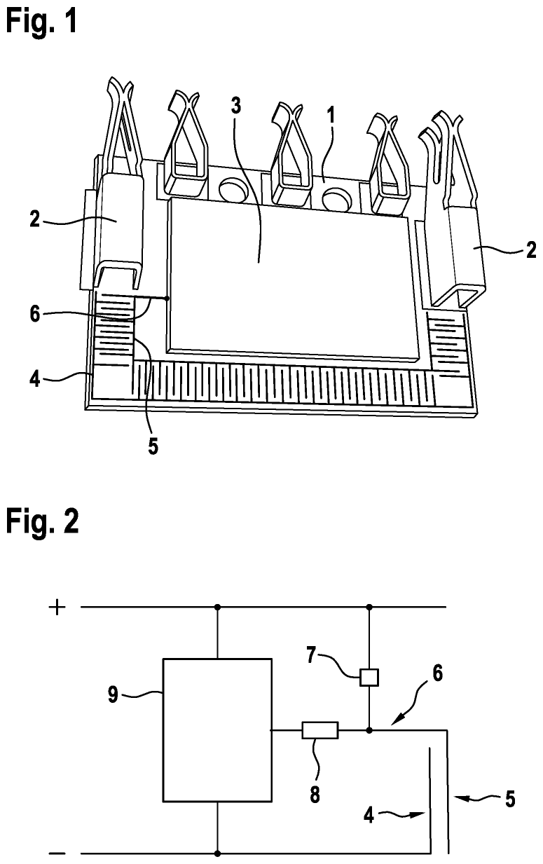

FIG. 1 a schematic representation of an electrical device in a first embodiment,

FIG. 2 a schematic representation of a first circuit,

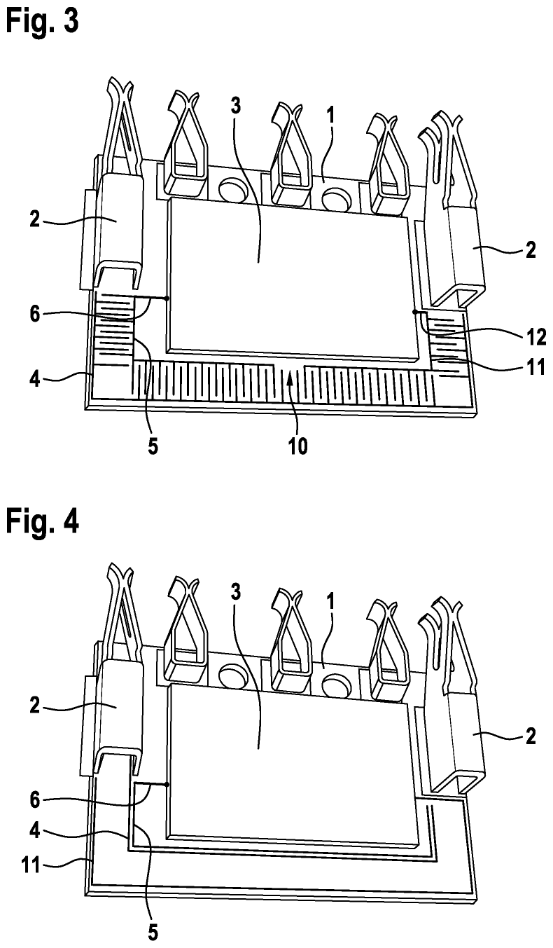

FIG. 3 a schematic representation of an electrical device in a second embodiment,

FIG. 4 a schematic representation of an electrical device in a third embodiment,

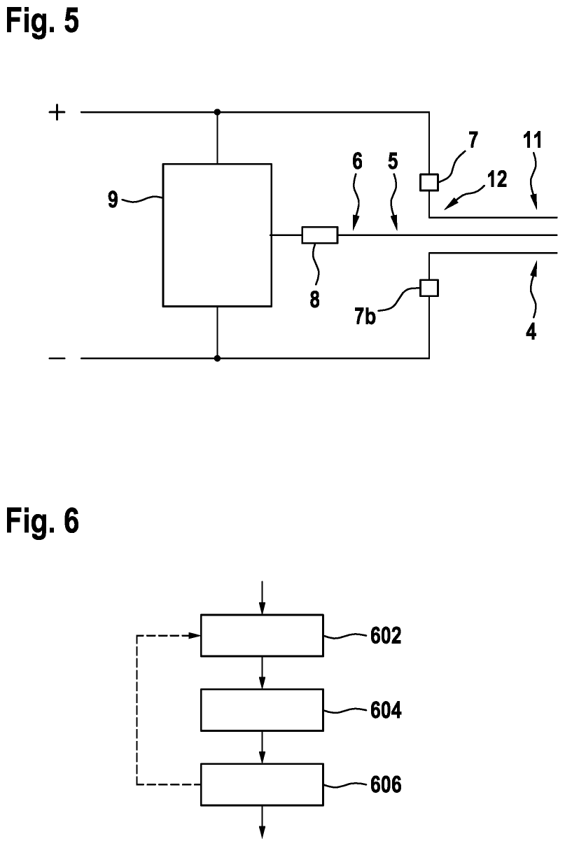

FIG. 5 a schematic representation of a second circuit,

FIG. 6 steps in a method for operating the electrical device.

Aspects of an electrical device are described below using the example of a battery charging system, which aspects may also be used for other electrical devices.

Electrically chargeable battery cells may be used to operate electrical devices without dependence on a power distribution network. In order to be able to use a higher voltage than that of a battery cell, it is typical to connect a plurality of battery cells in a battery pack. There are electrical devices that can be operated with a replaceable battery pack. When the battery pack is empty, the user can thus simply replace the battery pack with a full battery pack and continue to work without interruption.

In order to ensure that in a battery pack of multiple battery cells, each battery cell is operated within its specification, battery packs may have their own electronic components that monitor the cells for voltage and temperature, and, depending on the operating state, allow or do not allow charging and discharging. In this case, integrated dedicated circuits or also microcontrollers are used. The electronic components may be constructed on printed circuit boards.

When using battery packs, especially in power tools, but also in outdoor equipment or small automotive equipment, such as e-bikes, the equipment, battery packs and also chargers may be exposed to a dirty environment. Penetration of dirt and/or moisture into such an electrical device may result in unwanted electrical connections that affect functionality of the device, battery pack, or charger for charging the battery pack. In unfavorable cases, such contamination and/or moisture could also result in the safe operation being impaired. This is in particular the case when an amount of ingressed dirt and/or moisture is greater than expected.

Therefore, the electrical device may be constructed to be particularly protected against the ingress of water and dirt. Protection against moisture and dirt can be achieved, for example, with a casting of electronic components.

FIG. 1 shows a schematic representation of an electrical device in a first embodiment.

In the first embodiment, the electrical device comprises a printed circuit board 1 with contacts 2, the printed circuit board supporting at least one electronic component 3, e.g., for battery management. In the example, a first contact for a first potential and a second contact for a second potential that is different from the first potential are arranged on the printed circuit board 1. In the example, the first contact and the second contact are designed as contact springs or tulip contacts.

The at least one electronic component 3 is arranged on the printed circuit board 1. The electronic component 3 can be protected particularly against dirt or moisture. For example, the electronic component 3 is protected by a casting with a non-conductive media-resistant plastic, such as silicone. In the example, a first conductor 4 and a second conductor 5 are located in a region, not protected by the casting, of the printed circuit board 1. In the example, the first conductor 4 and the second conductor 5 are two adjacent conductive tracks that are not insulated from an environment of the printed circuit board 1. The first conductor 4 and the second conductor 5 can each have a finger structure. These finger structures may be nested within one another. The nested finger structures thus cover a particularly large surface area on the printed circuit board 1. The conductor 4 and the conductor 5 can have a uniform distance from one another at least in sections.

The first conductor 4 is electrically connected to one of the tulip contacts in this example. The electronic component 3 may be electrically connected to this tulip contact via a connection not shown in FIG. 1. The electronic component 3 may be electrically connected to the other of the tulip contacts via a connection not shown in FIG. 1.

In the example, a first connection 6 to a first circuit for detecting dirt or moisture is provided for the second conductor 5. In the example, the first circuit is arranged in the electronic component 3.

In FIG. 2, a schematic representation of the first circuit is depicted. The first circuit comprises the first connection 6, a first resistor 7, a second resistor 8 and an evaluation unit 9. The evaluation unit 9 may comprise a microcontroller.

In this example, the first conductor 4 is electrically connected to an input of the evaluation unit 9 for a reference potential of the electrical device. In the example shown in FIG. 2, a negative reference potential is provided as the first potential. In the example, this can be applied to the first contact.

In this example, the second conductor 5 is electrically connected via the first connection 6 and the first resistor 7 to an input of the evaluation unit 9 for a supply voltage of the electrical device. In the example shown in FIG. 2, a positive supply voltage is provided as the second potential. In the example, this can be applied to the second contact.

In this example, the second conductor 5 is electrically connected via the first connection 6 and the second resistor 8 to an input of the evaluation unit 9 for detecting dirt or moisture.

In the example, the input of the evaluation unit 9 for detecting dirt or moisture and the input of the evaluation unit 9 for a supply voltage of the electrical device are electrically connected via the first resistor 7 and the second resistor 8. The first resistor 7 is designed as a pull-up resistor. The second resistor 8 is designed as a protective resistor. The first resistor 7 and the second resistor 8 may be designed in series connection.

The evaluation unit 9 is thus able to easily determine whether there is contamination. Normally, there is no connection between the first conductor 4 and the second conductor 5. The evaluation unit 9 is configured to determine an applied potential at its input via the resistor 8. In the example, a high potential will be measured if there is no conductive connection between the first conductor 4 and the second conductor 5. Contamination represents a conductive connection between the first conductor 4 and the conductor 5. Since the first conductor 4 is connected to the reference potential in the example, the signal measured by the evaluation unit 9 in the case of determination will no longer be high but will be low.

According to a second embodiment shown schematically in FIG. 3, different regions of the printed circuit board 1 may be monitored separately. FIG. 3 shows an example of two regions that can be monitored separately.

In this example, the first conductor 4 is arranged as described for the first embodiment. In this case, the same first conductor 4 can be used for detection in both regions.

According to the second embodiment, two second conductors are provided. One of these conductors 5 is arranged adjacent to the first conductor 4, as described for the first embodiment, on one side of an interruption 10.

Another of these conductors 11 is arranged adjacent to the first conductor 4, as described for the first embodiment, on another side of an interruption 10. The conductor 11 is electrically connected to the evaluation unit 9 via a connection 12. For this purpose, a circuit for a connection of the conductor 11 via the connection 12 to a further input of the evaluation unit 9 for detecting dirt or moisture can be provided. This circuit may be configured as described for the connection 6 and the conductor 5. In this case, the evaluation unit 9 comprises two inputs for detecting dirt or moisture.

The evaluation unit 9 is thus able to easily determine whether there is contamination on one side of the interruption 10, on another side of the interruption 10 or on both sides of the interruption 10. In this case, the evaluation unit 9 can be configured to determine a respectively applied potential at both inputs as previously described.

The contamination can thus be reliably detected if conductive contamination has occurred. As a measure after such detection, it is possible to:
warn the user by means of an appropriate display device,
block further use,
restrict further use,
store the contamination event for any warranty evaluation.

Depending on the intended use of the electrical device, an appropriate measure can be selected.

If the electrical device comprises a battery pack that is protected from dirt or moisture, a blocking of further use may, for example, be provided, e.g., by deactivating. If contamination is expected according to the intended use because the battery pack is, for example, constructed to be dirt-tolerant by internal protective measures, a warning of the user may be provided, for example.

According to the second embodiment, different pairs of first conductor 4 and second conductor 5 may be arranged electrically insulated from one another in the electrical device, which conductors are electrically connected to different inputs of the evaluation unit 9.

In this case, the evaluation unit 9 is configured to determine a number of pairs for which the electrical connection has been detected. In this case, the evaluation unit 9 can be configured to determine a failure of the electrical device depending on the number.

According to a third embodiment, a first conductor 4 and a plurality of second conductors can be arranged adjacent to one another and electrically insulated from one another in the electrical device. In this case, the evaluation unit 9 is configured to determine a number of second conductors for which the electrical connection between the first conductor 4 to the second conductor is detected. In this case, the evaluation unit 9 can be configured to determine a failure of the electrical device depending on the number.

With this circuit, it is possible to monitor regions separately from one another, or to count contaminations of a lesser extent. For example, the evaluation unit 9 can be configured to trigger a warning if a single particle is detected. The evaluation unit 9 can, for example, be configured to control a light indicator, for example. For example, the evaluation unit 9 can comprise a communication interface and can be configured to send a message to a networked data terminal. The message may be sent upon detection of a particle. The evaluation unit 9 can be configured to block a battery pack for further use if a further particle is detected on another second conductor after a particle has been detected on a second conductor.

It may be provided to arrange more than two pairs in order to allow the evaluation unit 9 to use them to count further particles.

Monitored regions may be assigned to the pairs. Such subdividing into regions has the additional advantage that air gaps and creepage distances can be increased.

FIG. 4 shows a schematic representation of an electrical device in the third embodiment for two second conductors that are designated with 5 and 11 in FIG. 4.

Instead of or in addition to the detection of particles in different regions, the evaluation unit 9 according to the third embodiment can be configured to detect contaminations of different sizes.

In one aspect of the third embodiment, distances of different sizes are provided between the first conductor 4 and the conductor 5 and between the first conductor 4 and the conductor 11. The distance between the conductor 5 and the conductor 11 may substantially be the same as the distance between the first conductor 4 and the conductor 5 or between the first conductor 4 and the conductor 11.

The remaining components of the third embodiment in the example are designed correspondingly to the second embodiment described with reference to FIG. 3.

FIG. 5 shows a schematic representation of a second circuit for the third embodiment.

In contrast to the first circuit, the first conductor 4 in this example is electrically connected via a resistor 7b to the input of the evaluation unit for the reference potential. The conductor 11 is electrically connected with the resistor 7 to the input of the evaluation unit for the supply voltage. The conductor 5 is electrically connected via the resistor 8 to the input of the evaluation unit 9 for detecting dirt or moisture.

In this case, the evaluation unit 9 can be configured to determine a number of second conductors for which the electrical connection of the first conductor 4 to the second conductor is detected. In this case, the evaluation unit 9 can be configured to determine a failure of the electrical device depending on the number.

Instead of or in addition to the number, the evaluation unit 9 can be configured to determine a size or position of the contamination or the moisture depending on a designation of the input of the evaluation unit 9 at which the low potential has been determined.

The first conductor 4 in the example is connected to the reference potential. The evaluation unit 9 is configured to detect, via conductor 5, an electrical connection of conductor 5 to the first conductor 4 due to conductive contamination. The evaluation unit 9 is configured to detect, via conductor 5, conductive contamination of conductor 11 with the first conductor 4 due to conductive contamination. In the example, the distance between the conductor 11 and the first conductor 4 is greater than the distance between the conductor 5 and the first conductor 4. The evaluation unit 9 is configured to identify a large surface area of contamination in the case of a conductive connection of the conductor 11 to the first conductor 4. In contrast, the evaluation unit 9 is configured to identify a small surface area of contamination in the case of a conductive connection of the conductor 5 to the first conductor 4 without a conductive connection of the conductor 11 to the first conductor 4.

FIG. 6 schematically shows steps in a method for operating the electrical device.

In a step 602, it is checked whether an electrical connection of at least one first conductor 4 and at least one second conductor 5 due to dirt or moisture is detected by the evaluation unit 9.

If an electrical connection of at least one first conductor 4 and at least one second conductor 5 due to dirt or moisture is detected by the evaluation unit 9, a step 604 is carried out. Otherwise, step 602 is carried out.

In step 604, a failure is identified. For example, the failure is identified depending on an identified size of a particle or of a number of particles, or depending on a number of affected regions of the printed circuit board 1.

A measure is assigned to a failure in the example. As a measure, for example, it is possible to:
warn the user by means of an appropriate display device,
block further use,
restrict further use,
store the contamination event for any warranty evaluation.

In the example, it may be provided to deactivate the electrical device, discharge a battery cell with a discharge device, deactivate a charging device, or prevent charging of a battery cell by a charging device in the event of a failure.

Depending on the intended use of the electrical device, an appropriate measure is selected in the example from an assignment.

Subsequently, a step 606 is carried out.

In step 606, the selected measure is carried out.

For example, the user is warned by the appropriate display device, further use of the electrical device is blocked or restricted, or a contamination event for any warranty evaluation is stored or charging with a charging device is prevented. In the example, it may be provided to deactivate the electrical device, discharge a battery cell with a discharge device, or deactivate a charging device.

Step 602 may subsequently be carried out in order to continue monitoring, or the method may be terminated.

1. An electrical device, comprising:
a housing with a first external contact and a second external contact configured to supply the electrical device with power;
a first conductor;
a second conductor; and
an evaluation unit located in the housing and electrically connected to the first conductor and the second conductor,
wherein the first conductor is electrically connected to the first external contact,
wherein the first external contact is at a first potential,
wherein the second conductor is electrically connected to the second external contact,
wherein the second external contact is at a second potential that is different from the first potential, and
wherein the evaluation unit is configured to determine that there is dirt or moisture in the housing by detecting an electrical connection between the first conductor and the second conductor.

2. The electrical device according to claim 1, further comprising:
a first resistor configured to electrically connect the second conductor to an input of the evaluation unit for detecting the electrical connection.

3. The electrical device according to claim 2, further comprising:
a second resistor configured to electrically connect the second conductor to the second external contact and to another input of the evaluation unit to receive a supply voltage.

4. The electrical device according to claim 1, wherein the first conductor is electrically connected to an input of the evaluation unit to receive a reference potential.

5. The electrical device according to claim 1, wherein the first conductor and the second conductor are arranged electrically insulated from one another, (ii) in one region, at least in sections adjacent to one another, and (iii) uninsulated from one another.

6. The electrical device according to claim 1, wherein:
the evaluation unit is configured to identify a failure when the electrical connection between the first conductor and the second conductor due to the dirt or moisture has been detected, and
the evaluation unit is configured to deactivate the electrical device when the failure is identified.

7. The electrical device according to claim 6, further comprising:
a battery cell; and
a discharge device,
wherein the evaluation unit is configured to discharge the battery cell with the discharge device when the failure is identified.

8. The electrical device according to claim 6, further comprising:
a charging device for a battery cell, and
wherein the evaluation unit is configured to deactivate the charging device when the failure is identified, or (ii) prevent charging of the battery cell by the charging device when the failure is identified.

9. The electrical device according to claim 1, wherein:
the first conductor is included in a plurality of the first conductors,
the second conductor is included in a plurality of the second conductors,
different conductor pairs of the first conductors and the second conductors are arranged electrically insulated from one another in the electrical device and are electrically connected to different inputs of the evaluation unit,
the evaluation unit is configured to determine a number of the conductor pairs for which the electrical connection is detected, and
the evaluation unit is configured to identify the failure of the electrical device depending on the determined number of the conductor pairs.

10. The electrical device according to claim 1, wherein:
the second conductor is included in a plurality of the second conductors,
the first conductor and the plurality of the second conductors are arranged adjacent to one another and electrically insulated from one another, the evaluation unit is configured to determine a number of the second conductors for which the electrical connection of the first conductor to the second conductor is detected, and
the evaluation unit is configured to identify the failure of the electrical device depending on the determined number.

11. A method for operating an electrical device in which at least one first conductor, at least one second conductor and an evaluation unit are arranged, the method comprising:
detecting an electrical connection between the at least one first conductor and the at least one second conductor due to dirt or moisture using the evaluation unit
identifying a failure when the electrical connection is detected; and
warning a user using a display device when the failure is identified;
blocking or restricting a further use of the electrical device when the failure is identified;
storing a contamination event for any warranty evaluation when the failure is identified;
deactivating the electrical device when the failure is identified; and
discharging a battery cell with a discharge device, deactivating a charging device, or preventing charging with the charging device when the failure is identified.

12. The method according to claim 11, wherein:
the at least one first conductor is electrically connected to a first external contact
the first external contact is at first potential,
the at least one second conductor is electrically connected to a second external contact,
the second external contact is at a second potential that is different from the first potential, and
the at least one first conductor and the at least one second conductor are electrically connected to the evaluation unit.
